(19) United States
(12) Patent Application Publication
(10) Pub. No.: US 2020/0309888 A1
(43) Pub. Date: Oct. 1, 2020

(54) Radioprotectors and Electron Paramagnetic Resonance for Determination of Cellular Resistance to Ionizing Radiation without Radiation Exposure

(71) Applicant: The Henry M. Jackson Foundation for the Advancement of Military Medicine, Bethesda, MD (US)

(72) Inventors: Michael Daly, Washington, DC (US); Brian Hoffman, Evanston, IL (US)

(73) Assignee: The Henry M. Jackson Foundation for the Advancement of Military Medicine, Bethesda, MD (US)

(21) Appl. No.: 16/651,007

(22) PCT Filed: Sep. 28, 2018
(86) PCT No.: PCT/US2018/053475

§ 371 Date: Mar. 26, 2020

Related U.S. Application Data
(60) Provisional application No. 62/565,897, filed on Sep. 29, 2017.
(60) Provisional application No. 62/571,701, filed on Oct. 12, 2017.
(60) Provisional application No. 62/573,024, filed on Oct. 16, 2017.

(51) Int. Cl. G01R 33/60; G01N 24/10; G01T 1/02

(52) U.S. Cl. CPC G01R 33/60; G01T 1/02; G01N 24/10

(57) ABSTRACT

A method of predicting the resistance of a biological sample to the damaging effects of ionizing radiation applied to the biological sample is described, where the method includes measuring by electron paramagnetic resonance (EPR) spectroscopy the amount of divalent manganese (Mn²⁺) present in the biological sample; and then determining the resistance of the biological sample to the ionizing radiation based on the measured amount of the divalent manganese.

### STATEMENT REGARDING FEDERALLY SPONSORED RESEARCH OR DEVELOPMENT

This invention was made with government support under GM111097 awarded by the National Institutes of Health, under HDTRA1620354 and HDTRA1-15-1-0058 awarded by the Defense Threat Reduction Agency, and under FA9550-14-1-0118 awarded by the Air Force Office of Scientific Research. The government has certain rights in the invention.

### BACKGROUND OF THE INVENTION

Despite concerted functional genomic efforts, a genome sequence has not been found to be predictive of the level of cellular resistance to ionizing radiation (IR). Without the identification of a distinct set of genes responsible for IR resistance, sequence-based approaches to assessing the wide range of radiosensitivities encountered in prokaryotes, simple eukaryotes, and even human-derived cancer cell lines have been unsuccessful. Instead, genetic heterogeneity appears to be a central characteristic of IR resistant phenotypes.

It has been suggested that the presence of divalent manganese ions (Mn²⁺) in cells is responsible for extreme radiation resistance (Daly (2004) Science 306:1025-1028). It is known that reactive oxygen species (ROS) generated through the radiolysis of water (H₂O) in cells subjected to IR are the primary molecular agents of cellular damage. In particular, irradiated cells rapidly form superoxide (O₂^{•-}) ions by radiolytic reduction of both atmospheric oxygen (O₂), and O₂ released through the intracellular decomposition of IR-generated hydrogen peroxide (H₂O₂) as catalyzed by both enzymatic and non-enzymatic metal ions. Importantly, because superoxide is charged, it cannot easily cross membranes and therefore builds up in irradiated cells, selectively damaging proteins, not DNA (Daly (2009) Nat. Rev. Micriobiol. 7:237-245). Non-enzymatic cellular mechanisms exist to resist superoxide damage. Notably, the IR-resistant bacterium Lactobacillus plantarum, which naturally lacks antioxidant enzymes, is able to efficiently convert high concentrations of IR-induced superoxide generated under anaerobic conditions back to membrane-permeable H₂O₂(O₂^{•-}+2H⁺→H₂O₂) which readily escapes from the irradiated cells. This intracellular reaction is catalyzed in L. plantarum by antioxidant low-molecular weight (LMW) Mn²⁺ complexes. By comparison, the superoxide-scavenging, manganese-dependent enzyme superoxide dismutase (MnSod) becomes increasingly less effective as a catalyst as superoxide concentrations rise (Barnese (2010) J. Am. Chem. Soc. 132:12525-12527). This result may explain why MnSod has repeatedly been shown to be dispensable for IR resistance in bacteria and archaea, even though oxidative stress plays a major role in causing IR toxicity.

The least frequent and most dangerous form of DNA damage caused by IR is the double strand break (DSB). Impaired DSB repair currently provides the best available correlation with IR-induced cell death. Generally, any process that inhibits DSB repair—whether by mutation of repair genes or by ROS-mediated oxidative damage to repair enzymes—will severely limit a cell's ability to recover from IR. This has been established, first, by the greatly increased radiosensitivity of specific DNA repair-deficient mutants. Second, evidence has mounted that oxidative protein damage is causative in IR toxicity, and antioxidant LMW complexes of Mn²⁺ with metabolites are the source of ROS protection in vivo. Such intracellular manganese antioxidants globally protect the proteome (which logically must include DNA repair enzymes) from extreme oxidative assault during irradiation. Rationally-designed Deinococcus manganese antioxidants display similar properties in vitro and protect proteins, but not DNA or RNA, from IR, and are now used in the production of irradiated vaccines and as in vivo radioprotectors. In particular, the Mn²⁺-containing antioxidative peptide complexes present in Deinococcus radiodurans, a non-sporulating bacterium, are readily reconstituted and are non-toxic to animals. The peptide components include, for example, aspartic acid (D), glutamic acid (E), histidine (H), glycine (G), alanine (A) and methionine (M), but not proline (P). One such peptide based on the Deinococcus radiodurans complex now being used is the rationally-designed decapeptide DEHGTAVMLK (decapeptide 1, DP1), which yields a complex referred to as MDP, which forms spontaneously when DP1 (3 mM), MnCl₂ (1 mM) and Pi (25 mM potassium phosphate buffer (pH 7.4)) are combined. Under aqueous in vitro conditions, MDP protects the structure and function of proteins now used in the preparation of irradiated vaccines and the protection of animals from radiation.

Consistent with this focus on Mn²⁺ antioxidant complexes, it has been shown by absorption-display electron paramagnetic resonance (EPR) spectroscopy that the divalent manganese of D. radiodurans exists predominantly as high-symmetry (H) LMW complexes with phosphate, nitrogen, and other metabolites, with no evidence supporting significant amounts of Mn²⁺ bound to MnSod. IR-resistant Deinococcus bacteria accumulate high intracellular concentrations of high-symmetry divalent manganese ion (H—Mn²⁺) complexes, which are also in high population in cell extracts, whereas H—Mn²⁺ complexes are largely absent in radiosensitive bacteria or their cell extracts. LMW antioxidant protection has been identified as a critical component of IR resistance not only in bacteria and archaea, but also in a simple animal (ßdelloid rotifer). Two revelatory findings on the role of manganese antioxidants in protecting DNA repair enzymes were: first, LMW cell extracts of IR-resistant, Mn-accumulating bacteria, but not from IR-sensitive cells, specifically protect proteins from severe oxidative damage in vitro during high-dose irradiations; and second, Mn antioxidants do not significantly influence IR-induced DSB yields across bacteria with greatly differing IR resistances and antioxidant statuses. This disparity supports the hypothesis that proteins are the critical targets in IR-sensitive cells. However, the possibility that oxidative protein damage might also govern the functionality and efficiency of the recovery of eukaryotes has not been explored.

Deinococcus radiodurans is capable of surviving doses of IR, x-rays and gamma-rays (12-16 kGy) ten times greater than the yeast Saccharomyces cerevisiae, twenty times greater than the bacterium Escherichia coli, and 3,000 times greater than human cells. This extreme radiation resistance in D. radiodurans is chiefly attributed to the accumulation of LMW Mn²⁺ antioxidants, which protect the proteome from oxidation during exposure to IR, thereby preserving the high level of efficiency of its DNA repair systems.

D. radiodurans cultures typically progress from a relatively sensitive state during exponential growth to a more resistant state during the stationary phase, followed by a progressive loss of resistance as the culture ages. The shifts in radiation resistance correlate with changes in the electron paramagnetic resonance (EPR) spectra of the cells. At their most resistant, D. radiodurans exhibits Mn²⁺ high-symmetry EPR spectra, but as the cells become more radiation-sensitive, their EPR spectra broaden substantially.

### SUMMARY OF THE INVENTION

An aspect of the present invention is a method for predicting the resistance of a biological sample exposed to ionizing radiation, the method comprising: measuring by electron paramagnetic resonance spectroscopy the amount of divalent manganese present in the biological sample; and determining from the measured amount of the divalent manganese the predicted resistance of the biological sample to the ionizing radiation.

In an exemplary embodiment, the biological sample comprises one or more cells selected from the group consisting of archaea, bacteria and eukaryotes.

In an exemplary embodiment, the eukaryotic cells are from fungi or humans.

In an exemplary embodiment, the divalent manganese is a component in a low-molecular weight complex.

In an exemplary embodiment, the divalent manganese exists as a highly symmetrical complex.

In an exemplary embodiment, the divalent manganese complex contains phosphate and/or nitrogenous metabolites.

In an exemplary embodiment, the divalent manganese exists as a highly symmetrical complex with low-molecular weight metabolites.

In an exemplary embodiment, the ionizing radiation is gamma radiation or x-ray radiation.

In an exemplary embodiment, the divalent manganese that provides protection against IR-induced damage does not include the manganese-dependent enzyme superoxide dismutase.

In an exemplary embodiment, the biological sample is not subjected to the ionizing radiation at any time during the determination of the resistance of the biological sample to the damaging effects of ionizing radiation.

Another aspect of the present invention is a method of optimizing a therapeutically applied dosage of radiation to a mammal in need thereof, the method comprising: measuring by electron paramagnetic resonance spectroscopy the amount of divalent manganese present in the one or more cells; and determining from the measured amount of the divalent manganese in the cells the predicted resistance of the cells to the radiation.

In an exemplary embodiment, the mammal is a human.

In an exemplary embodiment, the one or more cells are cancer cells.

In an exemplary embodiment, the therapeutically applied dosage of radiation is radiotherapy.

Another aspect of the present invention is an oral (ingestible)/“anti-aging” antioxidant composition comprising: divalent manganese (Mn²⁺); a peptide; and phosphorus.

In an exemplary embodiment, the manganese, the peptide and the phosphorus present in the oral (ingestible)/“anti-aging” antioxidant composition form a complex.

In an exemplary embodiment, the phosphorus of the oral (ingestible)/“anti-aging” antioxidant composition is an orthophosphate.

In an exemplary embodiment, the peptide of the oral (ingestible)/“anti-aging” antioxidant composition comprises 5 to 30 amino acids.

In an exemplary embodiment, the peptide of the oral (ingestible)/“anti-aging” antioxidant composition is a decapeptide.

In an exemplary embodiment, the amino acids of the peptide of the oral (ingestible)/“anti-aging” antioxidant composition include one or more of aspartic acid (D), glutamic acid (E), histidine (H), glycine (G), alanine (A) and methionine (M).

In an exemplary embodiment, the amino acids of the peptide of the oral (ingestible)/“anti-aging” antioxidant composition include two or more of aspartic acid (D), glutamic acid (E), histidine (H), glycine (G), alanine (A) and methionine (M).

In an exemplary embodiment, the amino acids of the peptide of the oral (ingestible)/“anti-aging” antioxidant composition include three or more of aspartic acid (D), glutamic acid (E), histidine (H), glycine (G), alanine (A) and methionine (M).

In an exemplary embodiment, the amino acids of the peptide of the oral (ingestible)/“anti-aging” antioxidant composition include four or more of aspartic acid (D), glutamic acid (E), histidine (H), glycine (G), alanine (A) and methionine (M).

In an exemplary embodiment, the amino acids of the peptide of the oral (ingestible)/“anti-aging” antioxidant composition include five or more of aspartic acid (D), glutamic acid (E), histidine (H), glycine (G), alanine (A) and methionine (M).

In an exemplary embodiment, the amino acids of the peptide of the oral (ingestible)/“anti-aging” antioxidant composition are in their D-forms.

Another aspect of the present invention is a method for protecting a mammal from the damaging effects of radiation, the method comprising orally administering to the mammal an effective amount of the oral (ingestible)/“anti-aging” antioxidant composition described herein.

In an exemplary embodiment of the method for protecting a mammal from the damaging effects of radiation, the mammal is a human.

Another aspect of the present invention is a method of preparing an oral (ingestible)/“anti-aging” antioxidant composition as described herein, the method comprising: determining by electron paramagnetic resonance spectroscopy the predicted resistance of the composition to ionizing radiation.

Another aspect of the present invention is an oral (ingestible)/“anti-aging” antioxidant composition prepared by determining by electron paramagnetic resonance spectroscopy the predicted resistance of the composition to ionizing radiation.

### BRIEF DESCRIPTION OF THE DRAWINGS

FIG. 1A illustrates representative cellular IR survival in the form of IR survival curves and D10 values of the indicated strains. Bacteria and yeasts were grown, irradiated to the indicated doses (kGy), and then quantified for survival by a colony forming unit (CFU) assay. Values are provided for three independent trials with SDs shown. Shoulders on cell survival curves correspond with dose-dependent changes in the efficiency/accuracy of enzymatic repair (Daly (2012) DNA Repair (Amst) 11:12-21). FIG. 1B shows Mn²⁺ speciation in the form of a 35 GHz, 2K, 100 kHz field-modulated rapid-passage absorption-display EPR spectra of selected bacteria/yeasts/human Jurkat cells, normalized to maximum height. The “H” and “L” braces represent the field ranges over which H—Mn²⁺ and L-Mn²⁺ complexes contribute. The arrow indicates the monotonic decrease of L-Mn²⁺ contribution (increasing f_{H}) with increasing D10 (see Table 1 for the strain abbreviations). “JT” as an apparent exception is discussed herein and “Fe” represents Fe(III) signals. The conditions of the FIG. 1B spectra are as follows: MW frequency=34.8-34.9 GHz, T=2K, scan time=8 min, mod amp=2G. The FIG. 1B inset is a 35 GHz EPR spectrum of S. cerevisiae strain EXF-6218 along with a simulation obtained by summing the contributions from simulations of exemplary spectra representing the H—Mn²⁺ and L-Mn²⁺ pools (f_{H}=0.20).

FIG. 2A illustrates the antioxidant capacity of LMW extracts (ultrafiltrates, U) of bacteria (e.g., PpU) and yeasts (e.g., 6761U). The ROS-scavenging capacity of ultrafiltrates was assessed by an ORAC assay where Net AUC represents net area under the fluorescence decay curve. The ultrafiltrates were diluted to 0.01×, 0.02×, 0.03×, 0.04×, 0.05×, 0.1× and 0.2× for the assay. FIG. 2B illustrates the capacity of the ultrafiltrates of the indicated strains to protect proteins during gamma-irradiation. Indicated ultrafiltrates (U) were mixed with purified E. coli proteins, irradiated to the indicated doses (kGy) and assayed for protein damage (e.g., strand breaks, cross links, etc.), manifested as smears.

FIG. 3 illustrates the correlation between IR resistance (DSBD₁₀) and EPR speciation (f_{H}) plotted as the logarithm of the ratio f_{H}/f_{L}=f_{H}/(1−f_{H}) against the logarithm of DSBD₁₀. Symbols: bacteria (blue), yeasts (black), archaea (green), Jurkat (red); straight line, a fit to the Hill equation (equation 3b as described herein). The FIG. 3 inset is an analogous plot of speciation versus D₁₀.

FIG. 4 illustrates the EPR spectra of frozen cell suspensions of D. radiodurans (Dr), E. coli (Ec), Pi-bound Mn²⁺ and Mn²⁺-FosA (fosfomycin resistance enzymes) (Sharma (2013) PNAS 110:5945-5950). The signal from the majority of the Mn²⁺ in E. coli gives a spectrum characteristic of low-symmetry enzyme sites (such as FosA) in exhibiting broad wings. In contrast, the EPR spectrum of D. radiodurans is similar to that of phosphate-bound Mn²⁺ and therefore it appears that the Mn²⁺ accumulated by D. radiodurans is not bound to proteins and likely forms LMW reactive oxygen species (ROS)-scavenging complexes with various metabolites.

FIGS. 5 and 6 illustrate how D. radiodurans at late stages of growth displays low radiation resistance and low-symmetry EPR spectra, with FIG. 5 showing monitoring from 0 to 240 hours and FIG. 6 showing monitoring at 5 hours, 2 days, 6 days and 10 days.

FIG. 7 illustrates how the intracellular pool of Mn in D. radiodurans grows smaller as the culture ages.

FIG. 8 illustrates the performance of EPR as diagnostic of the differences in radiation sensitivity of exemplary cultured human and non-human cell types when exposed to ionizing radiation. The cultured mammalian cells were characterized for ionizing radiation resistance based on their ability to replicate and form colonies post-irradiation. The cells were pre-grown in Mn-replete rich media compositions prior to analysis by EPR. The EPR spectra are standardized for total Mn content. Conditions: 35 GHz, 2K. Cell lines: bovine pulmonary artery endothelial cells (BPAEC) (radiation-sensitive); human lung carcinoma cells (H1299) (moderately radiation-resistant); hamster ovary carcinoma (CHO) (moderately radiation-resistant); human cervical cancer cells (HeLa) (moderately radiation-resistant); human lung carcinoma cells (A549) (radiation-resistant); human Jurkat T cells (radiation-resistant).

### DETAILED DESCRIPTION OF THE INVENTION

### Definitions

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods, and materials are described.

As used herein, “a” or “an” means at least one, unless clearly indicated otherwise. The term “about,” unless otherwise indicated, refers to a value that is no more than 10% above or below the value being modified by the term. For example, the term “about 5% (w/w)” means a range of from 4.5% (w/w) to 5.5% (w/w).

The phrase “electron paramagnetic resonance (EPR) or electron spin resonance (ESR) spectroscopy” as used herein is a method for studying materials with unpaired electrons. EPR spectroscopy is particularly useful for studying metal complexes or organic radicals.

The term “gauging” as used herein is intended to be predictive in nature as opposed to an evaluation of the results after some action as occurred. In a specific instance, the term indicates that the biological sample has not actually been subjected to ionizing radiation and the results of the EPR measurement of the divalent manganese allows for an accurate assessment/prediction of how resistant the biological sample would be if subjected to ionizing radiation.

The phrase “ionizing radiation” as used herein refers to radiation that contains sufficient energy to free electrons from atoms or molecules, thereby ionizing them. Examples of ionizing radiation include gamma rays, x-rays and ultra-violet rays.

Functional genomic efforts over the last twenty years have failed to predict the ability of cells to survive ionizing radiation (IR). It is currently impossible to determine radiation resistance of a given cell type without actually exposing the cell to ionizing radiation. The present invention unexpectedly demonstrates that the amount of Mn²⁺, such as H—Mn²⁺, present in non-irradiated living cells can be readily and accurately assessed through the use of absorption-display electron paramagnetic resonance (EPR) spectroscopy and that this information is highly predictive of DNA repair efficiency of the cells and the ability of the cells to survive exposure to ionizing radiation. This spectroscopic measure of cellular Mn²⁺ content represents the strongest known biological indicator of cellular IR resistance between and within organisms across such diverse forms as archaea, bacteria and eukaryotes, with potential applications that include, for example, optimization of radiotherapy. Biological specimens (e.g., cancer biopsies or any living cells) can be subjected to EPR to provide a frequently critical answer—i.e., an accurate determination of the predicted resistance of the specimens to ionizing radiation. In addition, the efficacy of compositions, such as ingestible compositions, that contain manganese, a peptide, and phosphorus as radiation protectants (radioprotectants) can also be evaluated by use of EPR.

In the present invention, it was observed that an EPR spectrum correlates strongly with a cell's antioxidant status and resistance to ionizing radiation. In a particular embodiment, EPR was applied to a group of yeast (Saccharomyces cerevisiae) with radiation resistances ranging from the sensitivity of Escherichia coli to the limits of D. radiodurans and was used as a diagnostic tool to gauge the resistance of living bacteria and yeast to ionizing radiation.

The use of EPR in non-irradiated cells as highly diagnostic of the cells' IR survival and repair efficiency of DNA doublestrand breaks (DSB) was observed to broadly extend across archaea, bacteria and eukaryotes (including fungi and human cells). IR-insensitive cells, which are efficient at DSB repair, were observed to contain a high cellular content of divalent manganese (Mn²⁺) in high-symmetry (H) antioxidant complexes with small metabolites (e.g., orthophosphate and peptides) and exhibited narrow EPR signals (i.e., small zero-field splitting). In contrast, Mn²⁺ ions in IR-sensitive cells, which are inefficient at DSB repair, were observed to exist largely as low-symmetry (L) complexes with the substantially broadened EPR spectra commonly seen with enzymes and strongly chelating ligands. The discovery of the present invention that the fraction of cellular Mn²⁺ present as H-complexes (H—Mn²⁺), as measured by EPR of live, non-irradiated Mn-replete cells, represents the most accurate known gauge/predictor of biological IR resistance between and within organisms. Thus, it was observed that the antioxidant H—Mn²⁺ complexes and not the antioxidant enzymes (e.g., Mn superoxide dismutase), govern IR survival. As the pool of intracellular metabolites needed to form H—Mn²⁺ complexes depends on the nutritional status of the cell, the present invention concludes that IR resistance is predominantly a metabolic phenomenon. In a cross kingdom analysis, the significant differences in taxonomic classification, genome size and radioresistance between the cell-types studied and described herein further support the conclusion that IR resistance is not controlled by the repertoire of DNA repair and antioxidant enzymes.

The present invention is based in part on the observation that in nutrient-replete cells with adequate supplies of manganese, it is not the amount of the cellular Mn²⁺ and not the action of MnSod, that controls the in vivo IR resistance, but rather the extent to which Mn²⁺ (such as H—Mn²⁺) exists as complexes with antioxidant metabolites (such as LMW antioxidant metabolites)—i.e., the Mn²⁺ speciation. This finding results from a combination of two approaches: (i) that the IR resistance was measured across prokaryotes and eukaryotes of differing genome sizes by evaluating the double strand break (DSB) repair efficiency in terms of the index, DSBD₁₀, where this index represents the total number of double strand breaks generated per haploid genome when the cells are irradiated at the IR dose (Gy) needed to kill 90% of the population—a survival index named D₁₀ (Daly (2012) DNA Repair (Amst) 11:12-21; Daly (2004) Science 306:1025-1028); and (ii) that a simple measure of cellular Mn²⁺ speciation readily derived by absorption-display EPR spectroscopy of non-irradiated living cells (Sharma (2013) Proc. Natl. Acad. Sci. USA 110:5945-5950) correlates extremely well with the measured DSBD₁₀ for irradiated cell-types representing all three domains of life (archae, bacteria and eukaryotes) and can be used to determine cellular IR resistance in a real-time manner without actual exposure of the cells to IR. Thus, EPR is a suitable diagnostic tool for gauging IR resistance of any cell-type, with a potential application being the much needed optimization of radiotherapy dose in cancer patients (Scott (2017) Lancet. Oncol. 18:202-211).

The present invention also relates to an oral (ingestible)/“anti-aging” antioxidant composition comprising Mn²⁺, a peptide and phosphorus, where the efficacy of the radiation protective properties of the composition is readily determined by EPR. In an exemplary embodiment, the peptide is based on, for example, known backbone peptides (such as in the range 5-30 amino acids), the Mn²⁺ is in a suitable form (such as MnCl₂) and the phosphorus is an orthophosphate. In a particular embodiment, the peptide is produced in bulk from proteolytic digestion of casein, a by-product of the milk industry. Peptide pools derived from the casein are optimized by using a combination of standard proteases. In another exemplary embodiment, the Mn²⁺-containing antioxidant component of the oral (ingestible) composition is MDP or is based on MDP (such as a peptide containing one or two or three or four or five or six or seven or more of aspartic acid (D), glutamic acid (E), histidine (H), glycine (G), alanine (A) and methionine (M)) and is readily prepared from off-the-shelf ingredients available at a grocery or health food store. In a particular embodiment, the peptide components could be introduced as D-forms (rather than as L-forms), which would increase the metabolic half-life without compromising efficacy.

In an exemplary embodiment, the oral (ingestible) antioxidant composition is in a solid or semi-solid form. In another embodiment, the ingestible antioxidant composition is in liquid form and could be made available as a healthy beverage or elixir. In a particular embodiment, such a drink could be targeted in human populations over, for example, 40 years of age, when age-related proteome damage begins to manifest itself and protein oxidation begins to increase exponentially.

### EXAMPLES

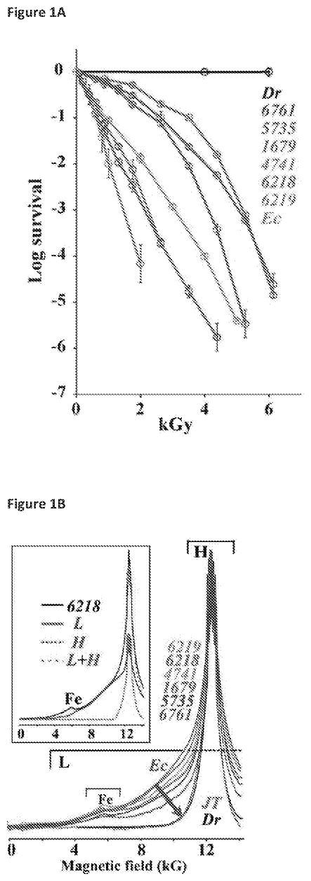

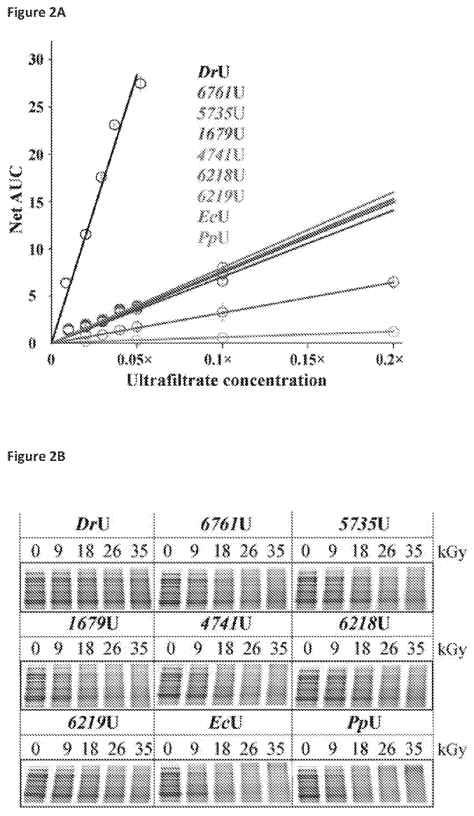

To carry out EPR measurements of Mn²⁺ speciation and to test for correlations with the measured IR survival (D₁₀) and repair efficiency (DSBD₁₀), cells from each member of the experimental panel (Table 1) were harvested at the middle to late-exponential growth phase, and the 35 GHz (Q-band) absorption-display EPR spectra were collected from the intact, viable cells. It had been previously found (Sharma (2013) Proc. Natl. Acad. Sci. USA 110:5945-5950) that the Q-band (35 GHz) continuous wave (CW) absorption-display EPR spectra, but not derivative spectra at the X- or Q-bands (at any frequency), reveal that cellular Mn²⁺ exists as two distinct pools of Mn²⁺ complexes. As illustrated in FIG. 1B, the g-2 region of the spectrum (approximately 12 kG) is dominated by a narrow signal (<1 kG in width) associated with antioxidant H—Mn²⁺ complexes with simple metabolites (e.g., orthophosphate), and which displays a sextet pattern arising from hyperfine interactions with the ⁵⁵Mn (I=5/2) nucleus (hyperfine coupling, with A approximately 90 G (Magnusson (1999) J. Am. Chem. Soc. 121:9764-9765; Reed (1984) EPR of Mn(II) complexes with enzymes and other proteins. Biological Magnetic Resonance, eds Berliner, Vol. 6, pp 73-142). This central H feature ‘rides on’ and is flanked by broad ‘wings’ extending from fields of approximately 2 kG to fields well above the magnet limit, which are associated with a heterogeneous population of low-symmetry (L) Mn²⁺ complexes. Previous observations further suggest that the relative amounts of the two pools may track with IR survival, D₁₀. In this regard, Mn²⁺ in D. radiodurans cells, which are extremely IR resistant, exists almost exclusively as antioxidant H-complexes, whereas Mn²⁺ in E. coli cells, which are IR sensitive, exists primarily as L-complexes (Sharma (2013) Proc. Natl. Acad. Sci. USA 110:5945-5950). In vivo, H—Mn²⁺ complexes in bacteria protect proteins (but not DNA) from IR-induced ROS (Daly (2004) Science 306:1025-1028); and similarly, synthetic H—Mn²⁺ complexes provide strong in vitro protection of proteins (but not DNA) from ROS (Daly (2007) PLoS Biol 5:e92). Moreover, H—Mn²⁺-accumulating yeasts consistently display elevated ROS-scavenging capacities (FIG. 2A) that protect proteins from gamma-irradiation (FIG. 2B), but have no effect on IR-induced DSB yields. Qualitative inspection of the absorption-display 35 GHz EPR spectra for bacteria and yeasts (FIG. 1A) provides support for this determination. In these normalized spectra, the intensity of the ‘wings’, which reflect the amount of L-Mn²⁺ relative to H—Mn²⁺ monotonically decreases with increasing cellular IR survival as measured by D10 (Table 1). However, human Jurkat T cells are outliers, displaying a spectrum essentially identical to that of the paradigmatic IR resistant bacterium, D. radiodurans, whereas its D₁₀ value indicates extreme IR sensitivity (FIG. 1B, Table 1).

### High-Frequency/High Field EPR

As described herein, MnSod is not responsible for the high IR survival of wild-type D. radiodurans as the IR resistance is undiminished in the isogenic D. radiodurans MnSod-deficient mutant (sodA⁻), as reported earlier (Daly (2004) Science 306:1025-1028) and confirmed herein (Table 1). Nonetheless, in consideration of reports based on high-frequency/high field (HFHF) EPR spectroscopy that Mn²⁺ Sod is abundant and critical in the IR survival of D. radiodurans, rather than the H—Mn²⁺ complexes (Bruch (2015) Metallomics 7:908-916), HFHF derivative-display EPR spectroscopy (Hassan (2000) J. Magn. Reson. 142:300-312) was used to determine the amount of Mn²⁺ Sod present in the D. radiodurans strains. HFHF EPR is notably more sensitive to the presence of Mn²⁺ Sod (Bruch (2015) Metallomics 7:908-916) than 35 GHz spectroscopy, which gave no evidence of Mn²⁺ Sod (Sharma (2013) Proc. Natl. Acad. Sci. USA 110:5945-5950). The spectrum of Mn²⁺ Sod collected at 321 GHz showed sharp, but low-intensity peaks across the g-2 region, with signature features to low and high field of the typical ⁵⁵Mn sextet at g-2 that comprises the spectrum for the H—Mn²⁺ of D. radiodurans. Through use of simulations of the D. radiodurans Mn²⁺ and Mn²⁺ Sod spectra to calibrate spectrum amplitudes, it was observed that Mn²⁺ Sod is present in negligible amounts, comprising at most approximately 5% of the total Mn²⁺ pool. As XANES measurements showed an absence of cellular Mn³⁺ (Daly (2007) PLoS Biol. 5:e92), the EPR measurements complement the survival measurements on the MnSod knockout strains by indicating that not only is Mn²⁺ Sod not responsible for the observed high cellular IR survival in these wild-type cells harvested in log phase (Table 1), but that in fact they contain little holo-MnSod of any kind. This observation was consistent with earlier HFHF measurements of MnSod populations in log phase (Bruch (2015) Metallomics 7:908-916). However, the earlier studies incorrectly concluded from the high MnSod population that was found in late stationary phase, that MnSod is responsible for high cellular survival throughout the growth cycle (Bruch (2015) Metallomics 7:908-916). Earlier data for the D. radiodurans MnSod-deficient mutant (DrsodA⁻) showed that this enzyme does not contribute to acute IR survival of log phase cells. Although late stationary phase cells were not tested (Sharma (2013) Proc. Natl. Acad. Sci. USA 110:5945-5950), it was noted that DrsodA⁻ displayed luxuriant growth on solid medium under high-level chronic IR (50 Gy/hour, ¹³⁷Cs) irrespective of the growth stage of inoculated cells (Daly (2004) Science 306:1025-1028). Moreover, E. coli sodA⁻ (Scott (1989) J. Biol. Chem. 264:2498-2501) and yeast sod⁻ mutants (Table 1) are as IR-resistant, if not more resistant, than the wild-types. Finally, the earlier HFHF work reported only the central portion of the MnSod spectrum. For completeness, collection and analysis of the full Mn²⁺ Sod spectrum has confirmed the reported magnitudes of the parameters that define the EPR spectrum of MnSod (the so-called Zero-Field-Splitting (ZFS) parameters), and further yields the sign of the dominant parameter (Gaidamakova (2012) Cell Host Microbe 12:117-124).

### Correlation of IR Sensitivity and EPR

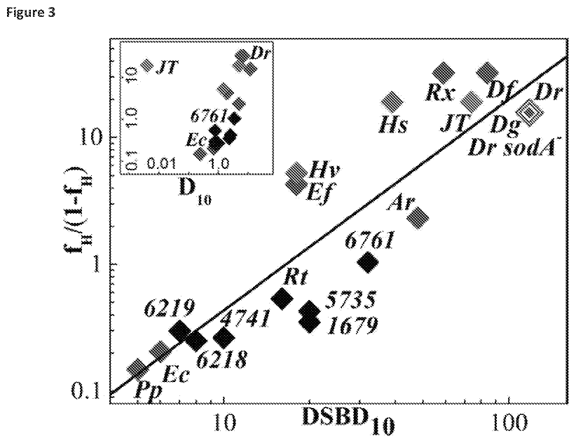

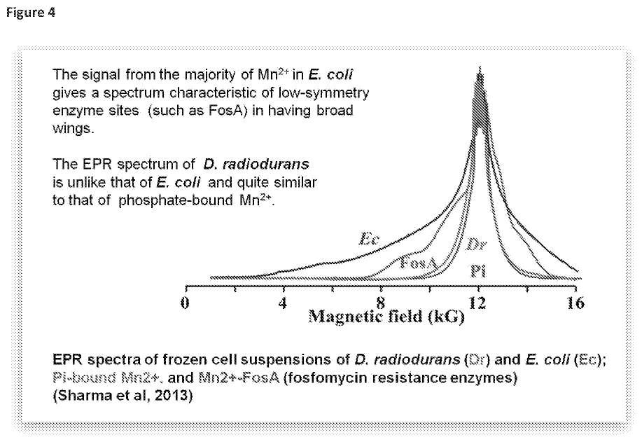

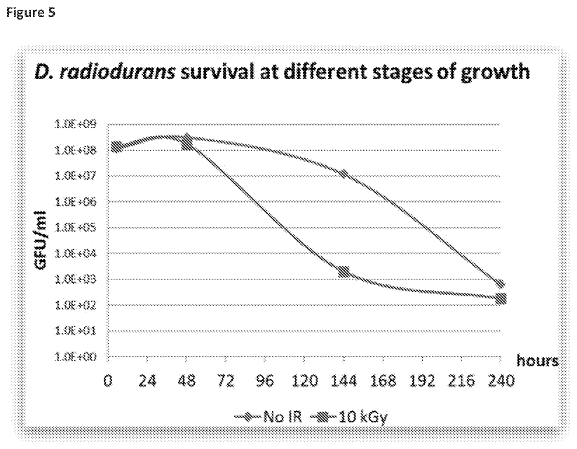

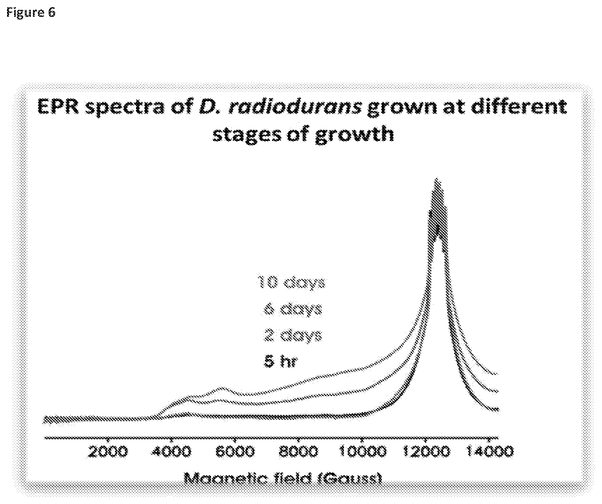

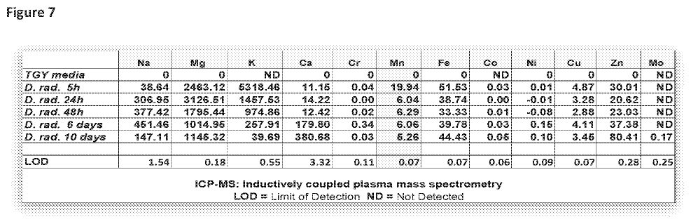

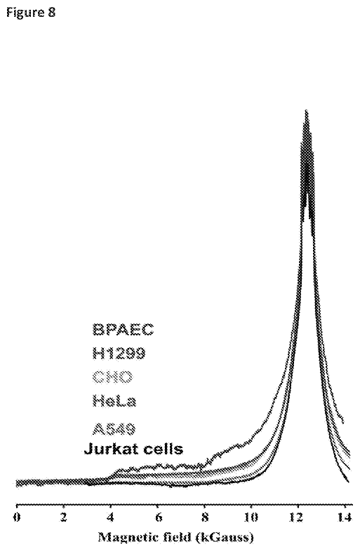

To quantify the correlation between increasing IR survival and an increasing population of H—Mn²⁺ complexes revealed in FIGS. 1A and 1B, a simple ‘quantitation by simulation’ procedure (Stoll (2014) Computational modeling and least-squares fitting of EPR Spectra. In Multifrequency Electron Paramagnetic Resonance: Data and Techniques, pp. 69-138; Yang (1987) Biophys. J. 51:55-67) using the EasySpin program (www.easyspin.org, EasySpin is a MATLAB toolbox for simulating a wide range of EPR spectra) was developed to decompose the cellular Mn²⁺35 GHz absorption-display EPR spectra into fractional contributions from spectra that represent the L and H pools. The contribution of the H—Mn²⁺ pool to the EPR spectrum of a cell-type was modeled as an optimized sum of a simulated exemplar spectrum that corresponds to that of the Pi complex of Mn²⁺ and of a simulated exemplar spectrum corresponding to that of Mn²⁺ with bound imidazole, where the presence of a bound imidazole contribution is observed when H—Mn²⁺ is dominant. In view of a study of the EPR of Mn²⁺ complexes (Horitani (2017) J. Am. Chem. Soc. 139:1984-1997), the broad features contributed by the heterogeneous cellular L-Mn²⁺ pool were modeled with a single exemplary spectrum in which the parameters that govern the breadth of a Mn²⁺ spectrum (ZFS parameters) (Magnusson (1999) J. Am. Chem. Soc. 121:9764-9765; Reed (1984) EPR of Mn(II) complexes with enzymes and other proteins. Biological Magnetic Resonance, eds Berliner, Vol. 6, pp 73-142) were larger and more widely distributed than those for H—Mn²⁺. For each cell-type, these exemplars were then summed in proportions that yield a match to the experimental spectrum. The total fraction of the H—Mn²⁺ contribution was given by the sum of the fractional contributions of the H-exemplars, f_{H}=f_{H′}+f_{H″} and the cellular L-Mn²⁺ pool then has a fraction f_{L}=1−f_{H}. An example of a two-component decomposition (H=H′; L) is shown for yeast strain EXF-6218, for which f_{H}=0.20 (FIG. 1B). Table 1 lists the f_{H} for each cell-type studied. As illustration of the range of speciation observed for the cell panel under normal growth conditions (Table 1), the Mn²⁺ of D. radiodurans and Jurkat cells is associated almost exclusively with H—Mn²⁺ complexes (f_{H} 0.95), whereas E. coli represents an opposite extreme, with a dominant population of L-Mn²⁺ complexes (f_{H}=0.17 and f_{L}=0.83). FIG. 3 displays several alternative forms of a plot of the variation of the fraction f_{H} of high-symmetry Mn²⁺complexes in cells that have not undergone IR exposure, as a function of DSBD₁₀ for the cell-type panel (Table 1). It has been shown that f_{H} correlates with DSBD₁₀ in a manner suggestive of an ‘IR resistance/binding isotherm’ (Reed (1984) EPR of Mn(II) complexes with enzymes and other proteins. Biological Magnetic Resonance, eds. Berliner, Vol. 6, pp 73-142) with f_{H} rising rapidly with increasing DSBD₁₀ from its lowest value (f_{H}=0.13) at DSBD₁₀=5 (Pp, Table 1) to f_{H}≲0.9 for DSBD₁₀ ≲60, and then essentially saturating thereafter. Such an isotherm is conveniently linearized in a ‘Hill plot’ (van Holde (2005) Principles of Physical Biochemistry (2nd Ed.) ISBN-13: 978-0130464279) of the EPR speciation, which plots the logarithm of the ratio of the fractional populations of H and L pools of Mn²⁺ (f_{H}/f_{L}=f_{H}/(1−f_{H})) against the logarithm of DSBD₁₀. Such a plot (FIG. 3) exhibits the strong linear correlation expected for an ‘IR resistance/binding isotherm’ (Pearson correlation coefficient=0.883, p-value=5.50×10⁻⁷; Spearman rank correlation coefficient=0.849, p-value=4.25×10⁻⁶). Conversely, this correlation over a range, 5≲DSBD₁₀ ≲118 implies that the speciation in live cells (the fraction of antioxidant H—Mn²⁺ as captured by the EPR-derived index f_{H}) is a powerful predictor of DSBD₁₀, which is based on survival as controlled for the genome size of the organism. FIG. 3 shows that D₁₀ is a suitable IR survival metric at the organism-level (e.g., yeasts), which naturally scales with genome size. FIG. 3 further provides evidence that DSBD₁₀ is the proper metric of IR resistance at the molecular level. In other words, the survival index, D₁₀ is a suitable measure of IR resistance only for cells of similar genome size, and for such cells the speciation from EPR is roughly correlated with D₁₀ (FIG. 3, inset), as expected, although not as well-correlated as with DSBD₁₀ (FIG. 3, main). However, comparing the use of these two IR tolerance measures for the human Jurkat cells clearly distinguishes between them. The Mn²⁺ EPR phenotype for Jurkat cells is ‘high H—Mn²⁺’, namely high f_{H} (FIG. 1B), implying high DSB repair efficiency in excellent correspondence with their DSBD₁₀ (FIG. 3). However, in the Hill plot of f_{H} versus the IR survival index (D₁₀) the Jurkat cells are hugely off the correlation shown by the other cells (FIG. 3, inset) because the extremely low D₁₀ index of the Jurkat cells does not account for the large Jurkat genome, and therefore the total number of DSBs which scales with genome size. Thus, the two plots of FIG. 3 demonstrate the genome size-based limitations of D₁₀ as a molecular measure of IR resistance. Overall, FIG. 3 shows that for diverse life forms over a range of thousands of Gy, the Mn²⁺ speciation within non-irradiated viable cells as determined by absorption-display EPR (f_{H}) has high predictive value for DSB repair efficiency as measured by the DSBD₁₀, and thus for resistance to IR exposure.

### Molecular Interpretation

In considering IR resistance, it is revealing to focus on f_{H}, wherein future improvements in the concentration measurements may allow a refinement of this approach. A molecular interpretation of the isotherm/Hill-plot correlation between the EPR and DSBD₁₀ measures emerges from a simple heuristic analysis of ligand binding by intracellular Mn²⁺. Guided by the decomposition of the cellular EPR spectra into contributions from two pools (FIG. 1B), Mn²⁺ complexes are divided into two types, H and L, with H representing an ‘average’ H′/H″ ligand. The assumption is that n H-ligands compete with n L ligands for binding to the cellular Mn²⁺. In all cell-types, the concentration of Mn²⁺ is significantly less than the concentrations of either ligand type, which ensures that there is a negligible amount of free Mn²⁺. For example, under standard growth conditions, D. radiodurans accumulates 105 Mn atoms per cell (Daly (2004) Science 306:1025-1028), but mM concentrations of Mn-binding LMW ligands (e.g., peptides and orthophosphate) (Daly (2010) PLoS One 5:e12570). Under these circumstances, the relative binding strengths of the populations of H and L ligands are simply represented by the product, Ki(Ci)ₙ, where i=H, L (H₂O ligands not explicitly denoted), where Ki and Ci respectively are the effective binding constants and concentrations of ligand type i=H, L This results in a binding isotherm (van Holde (2005) Principles of Physical Biochemistry (2nd Ed.) ISBN-13: 978-0130464279) that relates f_{H} to the ratio of ligand concentrations, C_{H}/C_{L}, as shown below in equation 1.

$${f}_{H} ( \frac{{C}_{H}}{{C}_{L}} ) = \frac{{{K}_{HL} ( \frac{{C}_{H}}{{C}_{L}} )}^{n}}{1 + {{K}_{HL} ( \frac{{C}_{H}}{{C}_{L}} )}^{n}} ; {K}_{HL} = \frac{{K}_{H}}{{K}_{L}} \qquad ( 1 )$$

As the key step that correlates IR resistance with Mn²⁺ speciation, we assign the DSBD₁₀ index as corresponding to (proportional to) the ratio of the concentrations of the ligand types as shown below in (2):

$${DSBD}_{10} ∝ \frac{{C}_{H}}{{C}_{L}} \qquad ( 2 )$$

which results in an ‘IR resistance isotherm’ that relates f_{H} to DSBD₁₀, as shown in equation 3a:

$${f}_{H} = \frac{{κ ( {DSBD}_{10} )}^{x}}{1 + {κ ( {DSBD}_{10} )}^{x}} \qquad ( 3 a )$$

where K represents the product of the ratio, K_{HL}=K_{H}/K_{L}, with the proportionality constant implied by equation 2. The validity of this treatment is highlighted by rewriting equation 3a as a linearized ‘Hill equation’ equation 3b (van Holde (2005) Principles of Physical Biochemistry (2nd Ed.) ISBN-13: 978-0130464279):

$$log ( \frac{{f}_{H}}{1 - {f}_{H}} ) = n log ( D S B {D}_{10} ) + log ( κ ) \qquad ( 3 b )$$

which precisely corresponds to the form of the correlation revealed by the plot in FIG. 3. The excellent representation of the data by equation 3b (FIG. 3) shows that the microscopic interpretation of DSBD₁₀ through equation 2 readily describes the correlation between IR resistance and EPR-determined speciation. Strong association between the EPR-derived metric f_{H} and the DSB repair efficiency metric DSBD₁₀ is supported by detailed statistical analysis. Specifically, linear regression of log₁₀[DSBD₁₀] (y-axis) versus log₁₀[f_{H}/(1−f_{H})] (x-axis) produced a coefficient of determination R²=0.78, suggesting that log₁₀[f_{H}/(1−f_{H})] explains 78% of the variance in log₁₀[DSBD₁₀]. To view f_{H} as a predictor of IR resistance, DSBD₁₀, one needs only invert equation 3b to obtain equation (4):

$$log ( {DSBD}_{10} ) = ( \frac{1}{n} ) log ( \frac{{f}_{H}}{1 - {f}_{H}} ) - log ( κ ) / n \qquad ( 4 )$$

and permute the axes of FIG. 3. With this molecular interpretation of DSBD₁₀, the meaning of the experimental correlation of FIG. 3 becomes clear: for nutrient-replete cells that have a sufficient amount of Mn²⁺, DSBD₁₀ directly correlates with the ratio of the concentrations of the H- and L-ligands (equation 2), which in turn determines the speciation of the cellular Mn²⁺ (equation 3(b)). Monte Carlo simulation has confirmed the robustness of the correlation between log₁₀[f_{H}/(1−f_{H})] and log₁₀[DSBD₁₀], taking into account realistic error distributions and magnitudes for both of these variables. In the most IR-resistant organisms, such as Deinococcus and Rubrobacter spp., the binding strength of the H-ligands far exceeds that of the L-ligands. The H-ligands overwhelmingly out-compete any L-ligands present, including the apo-superoxide dismutase polypeptide if present, driving the Mn²⁺ speciation to near-quantitative existence as LMW, IR-protective H—Mn²⁺ complexes (f_{H}→1). The observations reported here thus imply that in Mn²⁺ and nutrient-replete cells, the antioxidant H—Mn²⁺ complexes, as quantified by absorption-display EPR spectroscopy, govern IR survival in yeasts, archaea, bacteria, and human cells, as opposed to antioxidant enzymes, namely MnSod. This indicator of Mn²⁺ speciation was further strengthened with a widened panel of cell-type calibrants, studies of how f_{H} changed during cell growth and aging, further refinement of the EPR spectroscopic approach, and its complementation by electron-nuclear double resonance (ENDOR) studies (Sharma (2013) Proc. Natl. Acad. Sci. USA 110:5945-5950). In particular, human cells and their cancer cell counterparts can display large differences in their IR-sensitivities (6), and the H—Mn²⁺ content may be used to provide a suitable metric for determining dosing regimens for different cancer types during radiation therapy (FIG. 3).

In Mn-replete and nutrient-replete cells, the fraction of antioxidant metabolite complexes of Mn²⁺, the H—Mn²⁺, as captured by the EPR-derived index f_{H}, strongly correlated with the DSB repair efficiency index DSBD₁₀ (FIG. 3) (equations 2, 3(b)). This strong association was unexpected, considering the vast differences in taxonomic status, genome size and radioresistance between the studied cell-types. In contrast, the antioxidant enzyme MnSod played a negligible part in IR survival in such cells (Daly (2004) Science 306:1025-1028). The cellular content of H—Mn²⁺ complexes now appears to be the strongest biological indicator of cellular IR resistance between and within organisms representing the three domains of life. That MnSod confers no discernable advantage over the H—Mn²⁺ complexes for IR survival (Table 1) is expected from earlier studies (Daly (2004) Science 306:1025-1028). Metal-bound MnSod may be viewed as dispensable for IR resistance (FIG. 1A), and is shown herein to be absent or nearly so, in log phase D. radiodurans cells with extremely high IR survival. These findings suggest that in nutrient-replete organisms, H—Mn²⁺ complexes govern IR/ROS resistance.

This dominant role of H—Mn²⁺ in IR resistance of such cells further implies that MnSod may be more important under nutrient-limited conditions, when Mn²⁺ and Pi are in lower abundance and once the organic ligands (e.g., free amino acids, peptides and nucleosides) of H—Mn²⁺ complexes are consumed, typically in rapidly dividing cells or following starvation in aging cells (Daly (2004) Science 306:1025-1028). This study has extended insights on the role of Mn antioxidants in the IR survival (D₁₀) of bacteria to a group of simple eukaryotes by showing that variations in D₁₀ and efficiency of DNA repair (DSBD₁₀) among nine bacteria and nine yeasts are strongly correlated to their H—Mn²⁺ (f_{H}) content (Table 1). Importantly, the IR resistance of S. cerevisiae was shown not to be affected by the presence or absence of Sod enzymes, whether the major Cu/Zn-dependent SOD1, which is localized throughout the cell, or the Mn-dependent SOD2, which is only in the mitochondrial matrix (Table 1). Also consistent with this analysis, IR-induced DSB yields in S. cerevisiae genomes (0.0006-0.0009 DSB/Mbp/Gy) were observed to be similar to those reported in other organisms; IR-induced DSB-yields across representative archaea, bacteria, and animal cells fell within a narrow range of 0.001-0.005 DSB/Mbp/Gy (Table 1) (Daly (2012) DNA Repair (Amst) 11:12-21).

The ability of EPR to accurately measure differences in the IR survival between numerous phylogenetically distinct yeast strains of similar genome size makes paramagnetic spectroscopy suitable for gauging/predicting the IR resistance of other eukaryotic cell-types, including cancer cells. In the case of D. radiodurans, the 105 Mn²⁺ ions accumulated per cell are not uniformly distributed (Daly (2004) Science 306:1025-1028). Rather, the manganese is most concentrated in granules, often co-localized with the DNA-containing nucleoid (Daly (2007) PLoS Biol. 5:e92), which lends further support to the proposed Mn antioxidant role in repair of IR-induced DSBs, the most consequential form of DNA damage (Daly (2012) DNA Repair (Amst) 11:12-21). These granules may serve as primitive antioxidant organelle-like structures, strengthening the antioxidant protection in the proximity of the genome, where functional DNA repair and replication proteins are needed most. While the existence of high cellular content of H—Mn²⁺ complexes appears in species across archaea, bacteria and eukaryotes, many microbes can survive vastly greater IR doses than they ever would have experienced in their natural environment over geologic times. It therefore seems likely that the underlying metabolic systems for the accumulation of antioxidant H—Mn²⁺ complexes evolved not as a response to IR, but instead in response to other severe oxidative pressures that diminish proteome functionality (Slade (2011) Microbiol. Mol. Biol. Rev. 75:133-191): desiccation, ultraviolet (UV) light, aging, and other stressors. Gauging the antioxidant capacity of cells by EPR may thus have applications beyond radiobiology.

As D. radiodurans cultures grow, from exponential- to late stationary-phase, it was observed that the cells became less resistant to ionizing radiation. Such aging cells display changes in the Mn²⁺ EPR spectra from high symmetry to low symmetry. This transition is marked by depletion of the intracellular pool of LMW Mn antioxidants. IR resistance of S. cerevisiae strains also correlated strongly with the presence of high-symmetry EPR spectra, which became broadened as their resistance decreased. D. radiodurans and yeast strain 6761 are inferred to be resistant to IR-induced ROS because they accumulate an ample supply of LWM Mn antioxidants, which can be gauged by EPR.

### Materials

Bacteria: Deinococcus radiodurans (Dr) (ATCC BAA-816); Deinococcus radiodurans (DrsodA−) (sodA−) (Markillie (1999) J. Bacteriol. 181:666-669); Deinococcus geothermalis (Dg) (DSM 11300); Deinococcus ficus KS0460 (Df) (EXB L-1957) (Matrosova (2017) Stand. Genomic Sci. doi:10.1186/s40793-017-0258); Rubrobacter xylanophilus (Rx) (DSM 9941); Acinetobacter radioresistens (Ar) (MD929, USUHS); Enterococcus faecium (Ef) (ATCC 19434); Escherichia coli (Ec) (strain K-12) (MG1655); Pseudomonas putida (Pp) (ATCC 47054).

Yeasts: The eight S. cerevisiae strains and one Rhodotorula strain examined by EPR were chosen from a collection of fungi gauged for IR resistance (D₁₀) (Table 1): Saccharomyces cerevisiae (6761) (EXF-6761) (diploid); Saccharomyces cerevisiae (5735) (EXF-5735) (diploid); Saccharomyces cerevisiae (1679) (FY1679) (diploid) (Winston (1995) Yeast 11:53-55); Saccharomyces cerevisiae (6219) (EXF-6219) (diploid); Saccharomyces cerevisiae (6218) (EXF-6218) (diploid); Saccharomyces cerevisiae (4741) (BY4741) (haploid) (Brachmann (1998) Yeast 14:115-132); Saccharomyces cerevisiae (Scsod1⁻) (BY4741-^{Δ} SOD1) (haploid) (Reddi (2011) Genetics 189:1261-1270); Saccharomyces cerevisiae (Scsod2⁻) (BY4741-^{Δ} SOD2) (haploid) (Reddi (2011) Genetics 189:1261-1270); and Rhodotorula taiwanensis (Rt) (MD1149, USUHS) (accession number: PRJNA352283).

Archaea: Halobacterium salinarum (Hs) (ATCC 700922Δ) (Kish (2009) Environ. Microbiol. 11:1066-1078); Haloferax volcanii (Hv) (DS-70).

Human cells: Jurkat T cells (IT) (ATCC TIB-152).

EPR: As reported (Horitani (2017) J. Am. Chem. Soc. 139:1984-1997), cryogenic (2 K) Q-band (35 GHz) CW, 100 kHz field-modulated, dispersion-mode, rapid-passage absorption-display EPR spectra were collected on a spectrometer previously described (Werst (1991) J. Am. Chem. Soc. 113:1533-1538; Jhurry (2012) Biochemistry 51:5276-5284). High field, high-frequency (HFHF) EPR spectra were recorded on a laboratory-built spectrometer at the EMR facility of the NHMFL (Hassan (2000) J. Magn. Reson. 142:300-312).

D. radiodurans (ATCC BAA-816), was grown in TGY, at 32° C. 5 h to late log-phase (OD⁶⁰⁰ approximately 0.9), 24 h and 48 h to stationary-phase (OD⁶⁰⁰4.0), and cells were carried to starvation phase (6 and 10 days of culture) w/o changing the media. E. coli (K-12) was grown at 37° C. in TGY to OD⁶⁰⁰ approximately 0.9 (late log-phase).

Laboratory S. cerevisiae (BY4741 & FY1679), and environmental strains (EXF-6761, EXF-5735, EXF-6218, EXF-6219) obtained from MyCosmo (University of Ljubljana, Slovenia), were grown at 30° C. in YPD to OD⁶⁰⁰ approximately 0.9.

Irradiation of samples was performed in liquid media on wet ice at 12,000 Gy/hour (⁶⁰Co, 109-68 Irradiator, J. L Shepherd and Associates).

Cell ultrafiltrates: Aqueous-phase extracts of cell homogenates were subjected to ultracentrifugation, and then to ultrafiltration using 3 kDa filter units

EPR: The EPR absorption spectrum of a Mn²⁺ ion (S=5/2) in high field was examined using a Bruker EleXsys E580 spectrometer.

T4 DNA ligase assay: Phage T4 DNA ligase was irradiated in the presence or absence of ultrafiltrates, and following the radiation was assayed for residual ligase activity.

ORAC (Oxygen Radical Absorbance Capacity) assay: ROS-scavenging capacity was assayed by the decay of fluorescein due to the action of peroxyl radicals generated by AAPH (2,2′-azobis(2-methylpropionamidine)). In the presence of an antioxidant, radicals are scavenged and the fluorescence decay curve is retarded.

For IR Resistance, Survival (D₁₀) following gamma irradiation for a panel of cells from across bacteria, eukaryotes including fungi and human cells was determined as shown in Table 1 which shows values for prokaryotes and eukaryotes of the cell panel of the IR resistance indexes DSBD₁₀ (DSB repair efficiency) and D₁₀ (survival), DSB yield, genome size (GS) and the Mn²⁺ speciation index f_{H} as assessed by EPR.^{a}

TABLE 1

| | | | D₁₀, | DSB | GX, | |
|---|---|---|---|---|---|---|
| Full name | Short name | DSBD₁₀ | kGy | Yield | Mbp | f_{H} |
| Deinococcus radiodurans ATCC BAA-816* | Dr | 118 | 12.0 | 0.003 | 3.3 | 0.94 |
| Deinococcus radiodurans sodA− | Dr sodA⁻ | 118 | 12.0 | 0.003 | 3.3 | 0.94 |
| Deinococcus geothermalis DSM 11300 | Dg | 118 | 12.0 | 0.003 | 3.3 | 0.94 |
| Deinococcus ficus KS 0460 | Df | 84 | 7.0 | 0.003 | 4.0 | 0.97 |
| Jurkat T4 human cells ATCC TIB-152 | JT | 72 | 0.004 | 0.006 | 3000 | 0.95 |
| Rubrobacter xylanophilus DSM 9941 | Rx | 59 | 6.0 | 0.003 | 3.3 | 0.97 |
| Acinetobacter radioresistens MD929, USU | Ar | 48 | 5.0 | 0.003 | 3.2 | 0.7 |
| Halobacterium salinarum ATCC 700922 | Hs | 39 | 5.0 | 0.003 | 2.6 | 0.95 |
| Saccharomyces cerevisiae EXF-6761 | 6761 | 32 | 3.5 | 0.0009 | 10 | 0.51 |
| Saccharomyces cerevisiae EXF-5735 | 5735 | 20 | 2.6 | 0.00075 | 10 | 0.3 |
| Saccharomyces cerevisiae FY1679 | 1679 | 20 | 2.4 | 0.0007 | 12 | 0.26 |
| Haloferax volcanii DS-70 | Hv | 18 | 1.5 | 0.003 | 4.0 | 0.84 |
| Enterococcus faecium ATCC 19434 | Ef | 18 | 2.0 | 0.003 | 3.0 | 0.81 |
| Rhodotorula taiwanensis MD1149, USU | Rt | 16 | 0.8 | 0.001 | 20 | 0.35 |
| Saccharomyces cerevisiae BY4741 | 4741 | 10 | 1.0 | 0.0008 | 12 | 0.21 |
| Saccharomyces cerevisiae BY4741, sod1− | Sc sod1⁻ | 10 | 1.4 | 0.0008 | 12 | 0.21 |
| Saccharomyces cerevisiae BY4741, sod2− | Sc sod2⁻ | 10 | 1.1 | 0.0008 | 12 | 0.21 |
| Saccharomyces cerevisiae EXF-6219 | 6219 | 7 | 0.8 | 0.0006 | 14 | 0.23 |
| Saccharomyces cerevisiae EXF-6218 | 6218 | 8 | 0.8 | 0.00075 | 14 | 0.2 |
| Escherichia coli K-12, MG1655 | Ec | 6 | 0.7 | 0.002 | 4.6 | 0.17 |
| Pseudomonas putida ATCC 47054 | Pp | 5 | 0.3 | 0.003 | 6.1 | 0.13 |

^{a} Tabulated quantities: D10, dose at 10% survival (kGy); DSBD10 = [D10 (Gy)] × [DSB Yield (DSB/Mbp/Gy)] × [Genome size (Mbp)], bp = base pair, DSBs per haploid genome; DSB Yield (DSB/Mbp/Gy); GS, genome size (Mbp); f_{H}, fraction H—Mn²⁺. Gamma-radiation-induced cellular DSB damage is linear with dose, with DSB yields falling within narrow ranges: for circular genomes of prokaryotes (0.002 ± 0.001 DSB/Mbp/Gy); for linear genomes of animal cells (0.006 ± 0.002 DSB/Mbp/Gy); and for linear genomes of yeasts (0.0006 ± 0.0003 DSB/Mbp/Gy) (Matrosova (2017) Stand. Genomic Sci. doi: 10.1186/s40793-017-0258). Estimated uncertainties for f_{H}: <5%; Citations, references and Figures relating to DSB yields.

The panel incorporated eight S. cerevisiae strains with similarly-sized genomes (10-14 Mbp) from a collection of yeasts: two model laboratory strains—a haploid BY4741 and its diploid FY1679 counterpart; two MnSod-deficient mutants (Sod1 and Sod2) of strain BY4741, and four diploid environmental S. cerevisiae strains that were found to display significantly different IR resistances (FIG. 1A, Table 1). Basidiomycete Rhodotorula taiwanensis, which is a moderately IR-resistant yeast with a larger genome (20 Mbp) was added. Under standard conditions for cell-irradiation and pulsed field gel electrophoresis (PFGE), it was determined that the production of IR-induced DSBs for yeasts (BY4741, FY1679, EXF6219, EXF6761) ranged between 0.0006-0.0009 DSB/Mbp/Gy. Nine bacterial strains (D. radiodurans, a D. radiodurans MnSod-deficient mutant (sodA⁻), Deinococcus ficus, Deinococcus geothermalis, Rubrobacter xylanophilus, E. coli, Pseudomonas putida, Entercoccus faecium and Acinetobacter radioresistens) were also examined, with representatives previously characterized for Ir-induced DSB yields by PFGE (Daly (2004) Science 306:1025-1028); and similarly for two archaea, Halobacterium salinarum and Haloferax volcanii). As a representative of mammalian cells, which are significantly more susceptible to IR-induced DSBs than prokaryotes and yeasts due to their massive genome size (3 Gbp) (Daly (2012) DNA Repair (Amst) 11:12-21), cultured Jurkat T cells were selected. Jurkat cells are considered to be IR-resistant for human cells (D10, 4 Gy) (Chatterjee (2013) Nucleic Acids Res. 41:10157-10169), but extremely IR-sensitive compared to prokaryotes and fungi, based on D10 (Table 1). For each of the cell-types, D₁₀ (the IR survival index) and DSBD₁₀ (the DNA repair efficiency index defined as DSBD₁₀=[D₁₀ (Gy)]×[DSB Yield (DSB/Mbp/Gy)]×[Genome size (Mbp)]) were listed. The DSBD₁₀ index equals the number of DSBs inflicted per haploid genome at the IR dose that kills 90% of the population (FIG. 1A) and corresponds to an irradiated cell's maximum survivable number of IR-induced DSBs, and reflects its efficiency in repairing the most lethal form of DNA damage—the DSB (Table 1). The tabulated values of DSBD₁₀ for the cell panel shown in Table 1 span the gamut of IR resistance. Thus, as described (Daly (2012) DNA Repair (Amst) 11:12-21), the D. radiodurans strains are the most efficient at DSB repair (DSBD₁₀=118), whereas E. coli (DSBD₁₀=6) and P. putida (DSBD₁₀=5) are the least efficient, with the others arranged between these extremes. It is useful to emphasize that, as reported, the extremely high IR survival (D₁₀) of wild-type D. radiodurans is undiminished in the D. radiodurans MnSod-deficient mutant (sodA⁻) which is grown under high-level chronic gamma-radiation (50 Gy/h) or exposed to massive acute doses (12 kGy) (Table 1) (Daly (2004) Science 306:1025-1028). Therefore, this enzyme cannot be responsible for the high IR resistance observed in these cells.

The present invention has demonstrated that intracellular Mn²⁺ antioxidants shield protein-based enzymes, including repair enzymes, from the damage caused by ionizing radiation, allowing the cell to reassemble broken DNA and that the greater the number of such Mn²⁺ antioxidants the cell has (as determined by EPR), the more resistant to ionizing radiation the cell becomes. By providing such a surprisingly accurate predictor across diverse cell types of cellular resistance to ionizing radiation without the need for actual irradiation of the cells, the present invention is amendable to multiple applications such as personalized cancer treatments, the development of radioprotectors for people whose vocations expose them to frequent radiation (e.g., astronauts), the development of “anti-aging” beverages for people over 40, all while minimizing the need for animals in radiation studies.

While the invention has been described and illustrated herein by references to various specific materials, procedures and examples, it is understood that the invention is not restricted to the particular combinations of material and procedures selected for that purpose. Numerous variations of such details can be implied as will be appreciated by those skilled in the art. It is intended that the specification and examples be considered as exemplary, only, with the true scope and spirit of the invention being indicated by the following claims. All references, patents, and patent applications referred to in this application are herein incorporated by reference in their entirety.

1. A method for predicting the resistance of a biological sample exposed to ionizing radiation, the method comprising:
measuring by electron paramagnetic resonance spectroscopy the amount of divalent manganese present in the biological sample; and
determining from the measured amount of the divalent manganese the predicted resistance of the biological sample to the ionizing radiation.

2. The method of claim 1, wherein the biological sample comprises one or more cells selected from the group consisting of archaea, bacteria and eukaryotes.

3. The method of claim 2, wherein the eukaryotic cells are from fungi or humans.

4. The method of claim 1, wherein the divalent manganese is a component in a low-molecular weight complex.

5. The method of claim 1, wherein the divalent manganese exists as a highly symmetrical complex.

6. The method of claim 4, wherein the divalent manganese complex contains phosphate and/or nitrogenous metabolites.

7. The method of claim 1, wherein the divalent manganese exists as a highly symmetrical complex with low-molecular weight metabolites.

8. The method of claim 1, wherein the ionizing radiation is gamma radiation or x-ray radiation.

9. A method of optimizing a therapeutically applied dosage of radiation to a mammal in need thereof, the method comprising:
measuring by electron paramagnetic resonance spectroscopy the amount of divalent manganese present in the one or more cells; and
determining from the measured amount of the divalent manganese in the cells the predicted resistance of the cells to the radiation.

10. The method of claim 9, wherein the mammal is a human patient.

11. The method of claim 9, wherein the one or more cells are cancer cells.

12. The method of claim 9, wherein the therapeutically applied dosage of radiation is radiotherapy.

13. An oral antioxidant composition comprising:
manganese Mn²⁺;
a peptide; and
phosphorus.

14. The oral antioxidant composition according to claim 13, wherein the manganese, the peptide and the phosphorus form a complex.

15. The oral antioxidant composition according to claim 13, wherein the phosphorus is an orthophosphate.

16. The oral antioxidant composition according to claim 13, wherein the peptide comprises 5 to 30 amino acids.

17. The oral antioxidant composition according to claim 13, wherein the peptide is a decapeptide.

18. The oral antioxidant composition according to claim 16, wherein the amino acids include one or more of aspartic acid (D), glutamic acid (E), histidine (H), glycine (G), alanine (A) and methionine (M).

19. The oral antioxidant composition according to claim 16, where the amino acids include two or more of aspartic acid (D), glutamic acid (E), histidine (H), glycine (G), alanine (A) and methionine (M).

20. The oral antioxidant composition according to claim 16, wherein the amino acids are in their D-forms.

21. A method for protecting a mammal from the damaging effects of radiation, the method comprising orally administering to the mammal an effective amount of the oral antioxidant composition according to claim 13.

22. The method according to claim 21, wherein the mammal is a human.

23. A method of preparing the oral antioxidant composition of claim 13, the method comprising:
determining by electron paramagnetic resonance spectroscopy the predicted resistance of the composition to ionizing radiation.

24. A composition prepared by the method of claim 23.
